(19) United States
(12) Patent Application Publication
(10) Pub. No.: US 2012/0030899 A1
(43) Pub. Date: Feb. 9, 2012

(54) ELECTRICAL CONNECTOR FOR HANDLE AND WAND OF VACUUM CLEANER

(76) Inventors: Joe T. Lindsey, Harrodsburg, KY (US); Kyle C. Edmondson, Danville, KY (US)

(21) Appl. No.: 12/851,825

(22) Filed: Aug. 6, 2010

(51) Int. Cl. A47L 9/00; H05K 13/00; H01R 13/52

(52) U.S. Cl. 15/347; 439/137; 29/592.1

(57) ABSTRACT

The present invention relates to an electrical connector assembly including a male connector having a first plug body and a first electrical prong and a cooperating female connector having a second plug body with a cavity, a first electrical contact held in that cavity and a resilient shield received in the cavity. The resilient shield is displaceable from a first position covering the electrical contact and preventing intrusion of dirt and debris into the contact to a second position exposing the electrical contact for connection with the electrical prong.

### TECHNICAL FIELD AND INDUSTRIAL APPLICABILITY OF THE INVENTION

The present invention relates generally to the electrical connector field and more particularly to a novel electrical connector assembly and to a floor cleaning apparatus incorporating such an assembly.

### BACKGROUND OF THE INVENTION

It is well known in the art to equip a floor cleaning apparatus such as a canister vacuum cleaner, an upright vacuum cleaner and even an extractor with a cleaning wand assembly that may be connected with electrified attachments or cleaning tools. Such cleaning tools may incorporate one or more electrical operating systems including, but not limited to, an agitator drive motor, booster fans, work area lighting systems and the like. In order to power these electrical systems the floor cleaning apparatus must include an electrical power line extending from the power source, located in the main body of the floor cleaning apparatus, to the tool or attachment.

The present invention relates to an electrical connector assembly useful in providing power to just such electrical systems. The electrical connector assembly of the present invention includes cooperating male and female connectors that allow the various components of the floor cleaning apparatus, and more particularly the wand assembly, to be interconnected while maintaining the supply of electricity to the electrical system provided on the attachment or tool. Advantageously, the electrical connector assembly further includes a resilient shield adapted to keep dirt and debris out of the electrical contacts of the cooperating female connector when the female connector is disconnected from the cooperating male connector. This ensures that dirt and debris do not interfere with the electrical connection between the connectors when they are reconnected to utilize the floor cleaning apparatus.

### SUMMARY OF THE INVENTION

In accordance with the purposes of the present invention as described herein, an electrical connector assembly is provided. The electrical connector assembly includes a male connector and a cooperating female connector. The male connector includes a first plug body and a first electrical prong. The first electrical prong has a proximal end and a distal end. The proximal end of the first electrical prong is held in the first plug body.

The cooperating female connector includes a second plug body having a cavity. A first electrical contact is held in that cavity. In addition a resilient shield is received in the cavity. The resilient shield is displaceable from a first position covering the first electrical contact to a second position exposing the first electrical contact. Thus, in the first position the shield seals off the first electrical contact from the environment thereby preventing dirt and debris from fouling the first electrical contact. In contrast, in the second position the first electrical contact is exposed for simple connection with the first electrical prong.

Further describing the invention, a spring is received in the cavity. The spring biases the resilient shield into the first position. The resilient shield includes a first cam face at a first end, a second cam face at a second end and a substantially v-shaped body section connected to the first and second cam faces.

In accordance with an additional aspect of the present invention a floor cleaning apparatus is provided. The floor cleaning apparatus comprises a housing including a nozzle assembly and a canister assembly. A suction generator is carried on the housing. A dirt collection vessel is also carried on the housing. In addition, the floor cleaning apparatus includes a wand assembly having a flexible hose, an operator handle and a wand. The wand assembly further includes an electrical connector assembly.

The electrical connector assembly is characterized by having a male connector and a cooperating female connector. The male connector includes a first plug body and a first electrical prong. The first electrical prong has a proximal end and a distal end. The proximal end of the first electrical prong is received and held in the first plug body.

The cooperating female connector includes a second plug body having a cavity. A first electrical contact is held in that cavity. In addition, a resilient shield is received in the cavity. The resilient shield is displaceable from a first position, covering the first electrical contact and protecting that contact from dirt intrusion, to a second position exposing the first electrical contact for connection with the first electrical prong.

In accordance with yet another aspect of the present invention a method of resisting dirt intrusion into a female electrical connector is provided. That method comprises the step of providing a first electrical contact of the female electrical connector in a cavity of a plug body and providing a resilient shield in that cavity. The resilient shield is displaceable from a first position covering the first electrical contact to a second position exposing the first electrical contact for connection with a first electrical prong of a male connector.

In the following description there is shown and described several different embodiments of the invention, simply by way of illustration of some of the modes best suited to carry out the invention. As it will be realized, the invention is capable of other different embodiments and its several details are capable of modification in various, obvious aspects all without departing from the invention. Accordingly, the drawings and descriptions will be regarded as illustrative in nature and not as restrictive.

### BRIEF DESCRIPTION OF THE DRAWINGS

The accompanying drawings incorporated herein and forming a part of the specification, illustrate several aspects of the present invention and together with the description serve to explain certain principles of the invention. In the drawings:

FIG. 1 is a perspective view of a floor cleaning apparatus in the form of a canister vacuum cleaner incorporating the electrical connector assembly of the present invention;

FIG. 2 is a detailed exploded perspective view illustrating the flexible hose and operator handle of the wand assembly of the canister vacuum cleaner illustrated in FIG. 1;

FIG. 3 is a detailed exploded perspective view of the wand assembly of the canister vacuum cleaner illustrated in FIG. 1;

FIG. 4a is a detailed cross sectional view illustrating the cooperating female connector of the electrical connector assembly of the present invention with the resilient shield in the first position covering the electrical contacts of the female connector to prevent intrusion of dirt and debris into those contacts;

FIG. 4b is a detailed cross sectional view similar to FIG. 4a but illustrating the resilient shield in the second position exposing the electrical contacts of the female connector for connection with the electrical prongs of the cooperating male connector;

FIG. 5 is a schematical block diagram illustrating the present invention connected to a floor cleaning apparatus incorporating a telescoping wand assembly as well as a power tool attachment that may be connected to the distal end of the wand assembly or, alternatively, directly to the operator handle on the end of the flexible hose of the wand assembly; and

FIG. 6 is a detailed perspective view of the resilient shield and the associated spring.

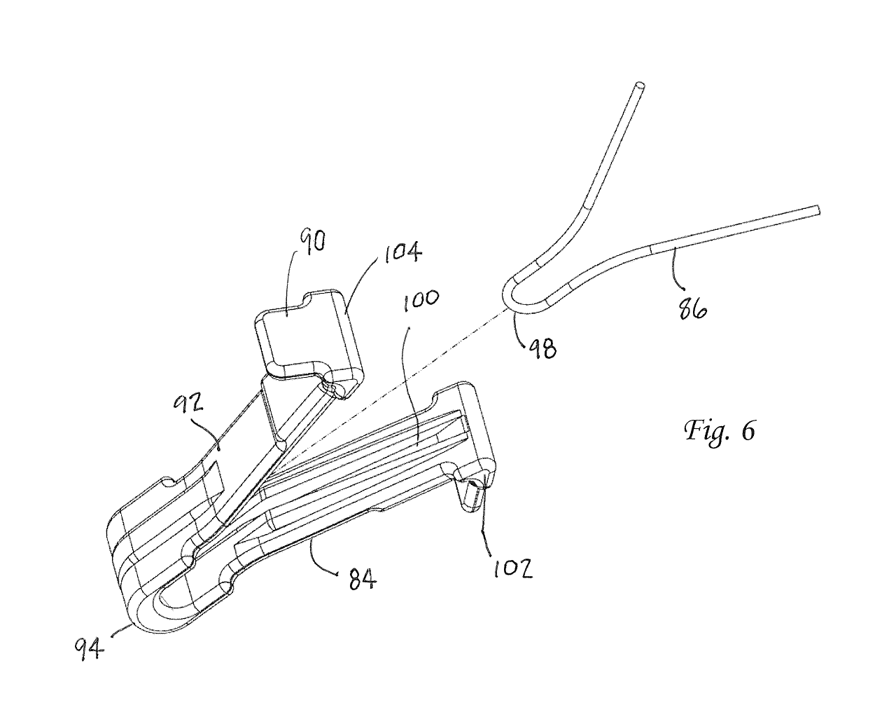

Reference will now be made in detail to the present preferred embodiment of the invention, examples of which are illustrated in the accompanying drawings.

### DETAILED DESCRIPTION OF THE PREFERRED EMBODIMENTS OF THE INVENTION

Reference is now made to the drawing figures illustrating a floor care apparatus in the form of a canister vacuum cleaner 10 incorporating the electrical connector assembly 60 of the present invention. While a canister vacuum cleaner 10 is illustrated, it should be appreciated that the floor care apparatus of the present invention may comprise a different apparatus such as, for example, an upright vacuum cleaner or even an extractor. Thus, the present invention should not be interpreted as being limited to a canister vacuum cleaner 10 as illustrated.

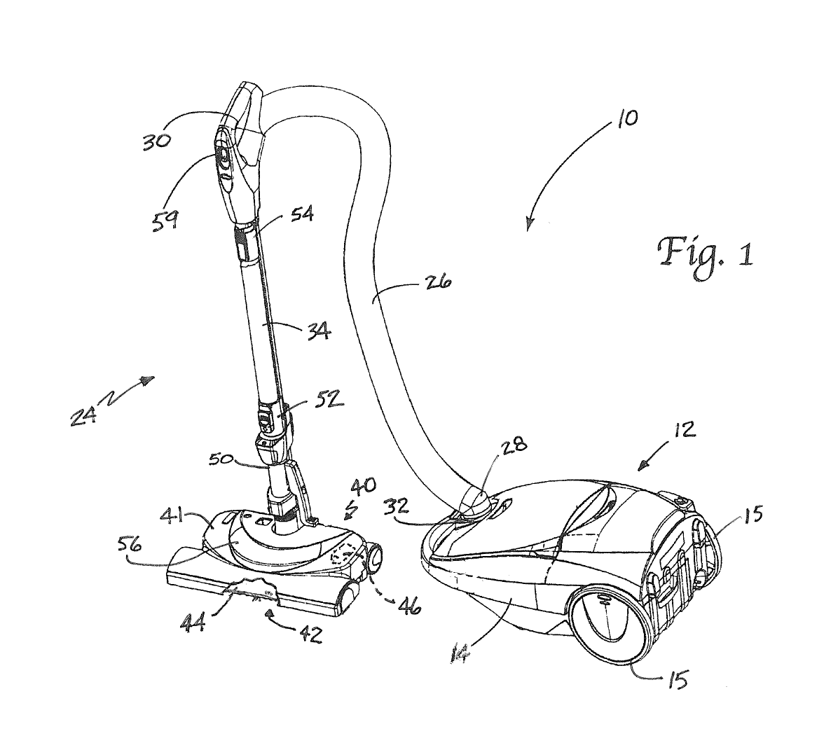

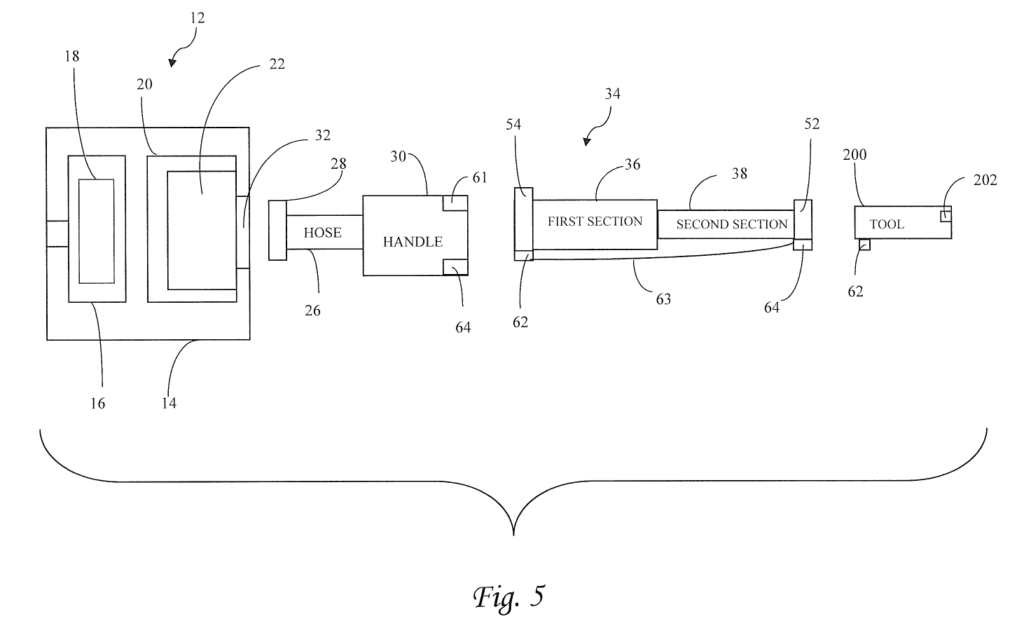

As best illustrated in FIGS. 1 and 5, the canister vacuum cleaner 10 includes a canister assembly 12 having a housing 14 supported for movement across the floor on ground engaging wheels 15. The housing 14 includes an internal motor compartment 16 for receiving a suction generator 18 as well as a dirt collection compartment 20 for receiving a disposable filter/cleaning bag 22.

The canister vacuum cleaner 10 further includes a wand assembly, generally designated by reference numeral 24. The wand assembly 24 includes a flexible hose 26 having a hose cuff 28 at one end and an operating handle 30 at the opposite end. The hose cuff 28 may be releasably connected to an inlet port 32 provided on the housing 14 so as to allow direct communication from the flexible hose to the cleaning bag 22 held in the dirt collection compartment 20. The wand assembly 24 further includes a wand 34. In the embodiment illustrated in FIG. 1, the wand 34 is of one piece tubular construction. In the alternative embodiment illustrated in FIG. 5, the wand 34 is a telescoping wand including first and second telescoping sections 36, 38.

The canister vacuum cleaner 10 further includes a nozzle assembly generally designated by reference numeral 40. The nozzle assembly 40 includes an outer housing 41 that forms an agitator cavity/suction inlet 42 for receiving a rotary agitator 44 of a type well known in the art. The nozzle assembly 40 further includes an agitator drive motor 46 for driving the rotary agitator 44. The agitator cavity/suction inlet 42 is provided in fluid communication with an outlet port 50. A first connector 52 on the distal end of the wand 34 is releasably connected to the outlet port 50 while a second connector 54 on the opposite or proximal end of the wand 34 is connected to the operator handle 30.

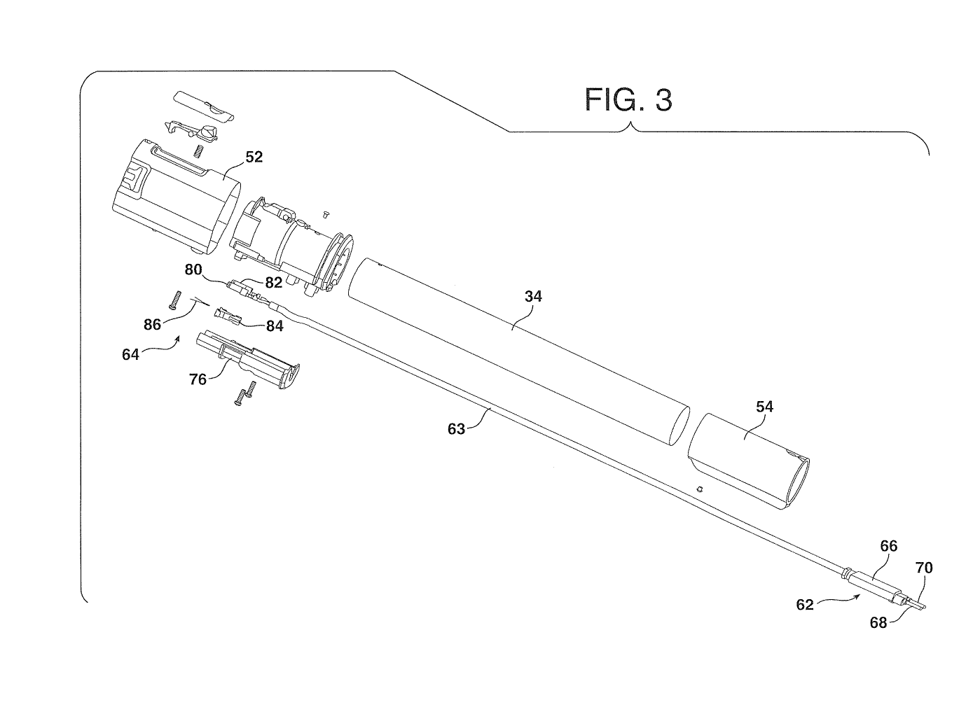

As should be appreciated, it is necessary to provide power to the agitator drive motor 46 and any light source 56 as well as any other electrical system provided on the nozzle assembly 40. This is accomplished by the electrical connector assembly 60 (see FIGS. 3, 4a, 4b and 5) which delivers electrical power from the canister assembly 12 to the nozzle assembly 40.

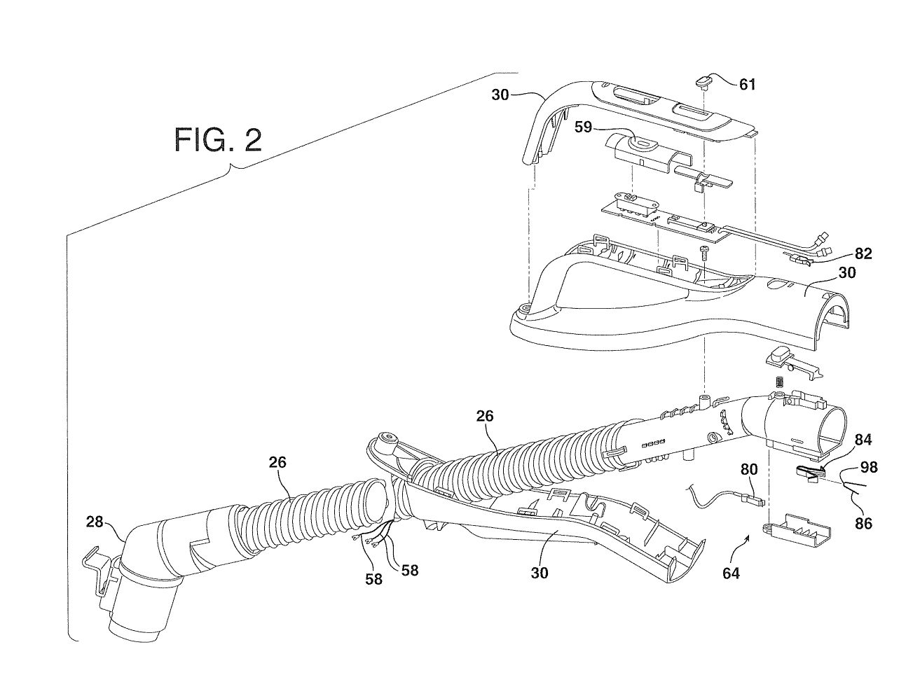

More specifically, as illustrated in FIG. 2, electrical power travels from a source in the canister assembly 12 through the hose cuff 28 and along the hose 26 to the operator handle 30 by means of a contact connection (not shown) between the cuff and the canister assembly and a series of electrical wires 58 in a manner known in the art (note wires 58 wound around hose 26). The electrical wires 58 are connected with the operator controls on the handle 30 such as a suction generator actuator 59 and an agitator control switch 61. More specifically, the suction generator actuator 59 allows the operator to turn the suction generator 18 on and off. In contrast, the agitator control switch 61 allows the operator to interrupt power to the agitator drive motor 46 when the suction generator 18 is on so as to interrupt the agitator drive for bare floor cleaning. The electrical connector 60 of the present invention provides for electrical connection between the operator handle 30 and the electrical systems provided on the nozzle assembly 40.

More specifically, the electrical connector 60 may be generally described as including a female connector 64 provided on the operator handle 30, a cooperating male connector provided on the connector 54 of the wand 34, another or second female connector 64 provided on the first connector 52 at the opposite end of the wand 34 and a second male connector 62 provided on the nozzle assembly 40 adjacent the outlet port 50 (see FIGS. 2, 3, 4a, 4b and 5). Electrical lines (not shown) connect the female connector 64 on the operator handle 30 with the agitator control switch 61. Electrical lines 63 connect the male connector 62 and second female connector 64 on the wand 34. Additional electrical lines (not shown) connect the male connector 62 on the nozzle assembly 40 with the agitator drive motor 46, light source 56 or other operating electrical system on the nozzle assembly (see FIGS. 2, 3 and 5).

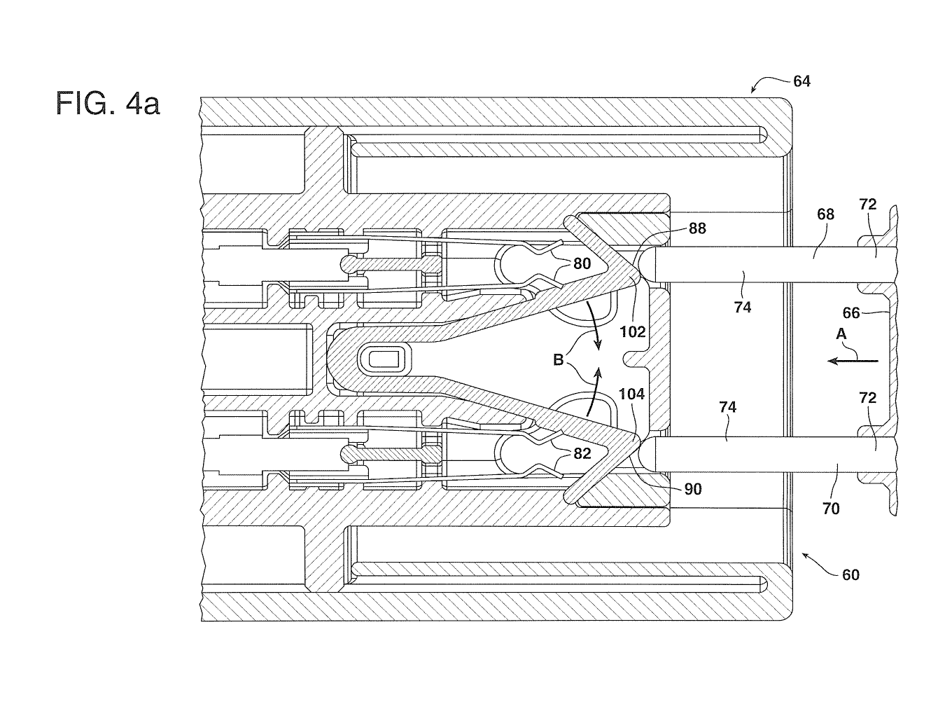

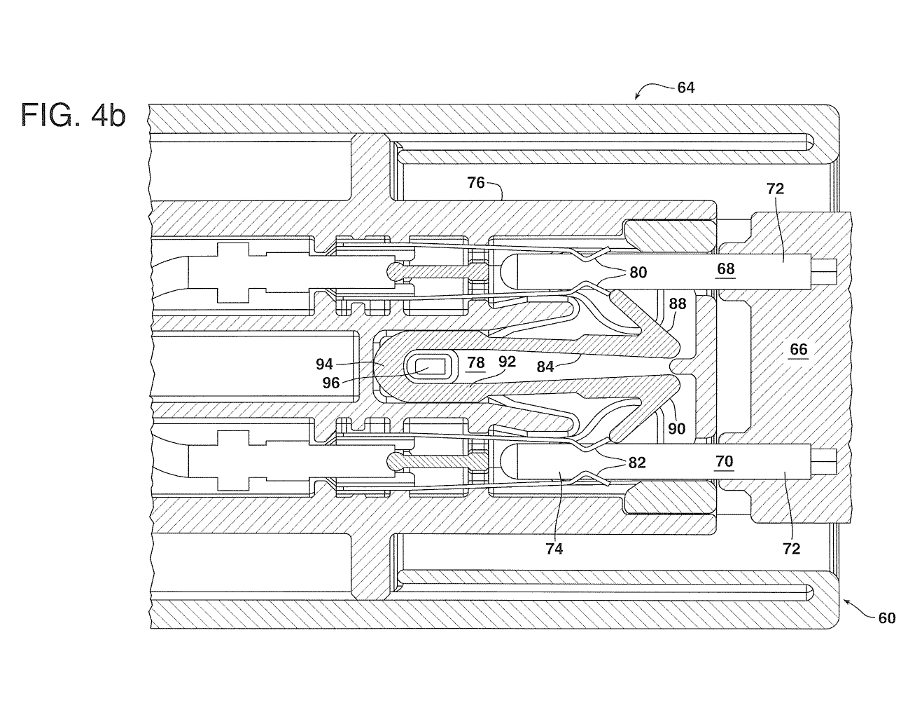

As best illustrated in FIG. 3, each male connector 62 includes a first plug body 66, a first electrical prong 68 and a second electrical prong 70. The proximal ends 72 of the prongs 68, 70 are held in the plug body 66 while the distal ends 74 project from the body (see also FIGS. 4a and 4b).

As best illustrated in FIGS. 2, 3, 4a and 4b, each female connector 64 includes a second plug body 76 having a cavity 78. First and second electrical contacts 80, 82 are received in the cavity 78. In addition, a resilient shield 84 is also received in the cavity 78. As illustrated and described in greater detail below, the resilient shield 84 is displaceable from a first position (shown in FIG. 4a) and a second position (illustrated in FIG. 4b). In the first position the shield 84 covers the electrical contacts 80, 82 and protects them from intrusion with dirt and debris. In the second position, the shield 84 exposes the electrical contacts 80, 82 for connection with the first and second electrical prongs 68, 70 of the cooperating male connector 62. A spring 86 is received in the cavity and functions to bias the resilient shield 84 into the first position.

More specifically, the resilient shield 84 includes a first cam face 88 at a first end, a second cam face 90 at a second end and a substantially v-shaped body section 92 intermediate the two cam faces. The body section 92 includes a first bend 94 and the plug body 76 includes a boss 96. When properly mounted in the cavity 78, the first bend 94 of the body section 92 is received around the boss 96.

As should further be appreciated, the spring 86 is also substantially v-shaped and includes a second bend 98 (see FIG. 4a). The spring 86 is received against the body section 92 in a groove 100 on the body section with the second bend 98 also received around the boss 96. The resilient shield 84 is made from a non-conducting polymer material such as, for example, polypropylene or delrin.

Reference is now made to FIG. 4a illustrating the resilient shield 84 in the first position with the first end 102 covering the first electrical contact 80 and the second end 104 covering the second electrical contact 82. By covering the contacts 80, 82 when they are disconnected from the prong 68, 70 of the cooperating male connector 62 intrusion of dirt and debris into the contacts is substantially prevented. This prevents fouling of those contacts 80, 82 and maintains the integrity of any electrical connection.

When an operator wishes to connect a male connector 62 to a female connector 64, the operator aligns the first and second electrical prongs 68, 70 of the male connector 62 with the first and second electrical contacts 80, 82 of the female connector 64 (see FIG. 4a) which are accessible through openings in the plug body 76. Next, the operator pushes the prongs 68, 70 of the male connector 62 into the female connector 64 (note action arrow A). When this is done, the distal end of the first prong 68 initially engages the first cam face 88 while the distal end of the second prong 70 initially engages the second cam face 90. As the operator continues to push the male connector 62 and the female connector 64 together, engagement between the distal ends of the prongs 68, 70 and the cam faces 88, 90 cause the ends 102, 104 of the resilient shield 84 to be displaced inwardly in the direction of action arrows B. As illustrated in FIG. 4b, eventually the ends 102, 104 are displaced into the second position so that the contacts 80, 82 are completely uncovered and are open to receive the prongs 68, 70 and complete the electrical connection.

As should be appreciated from viewing FIG. 5, the vacuum cleaner 10 may include an attachment or tool 200 with a male connector 62 that may be connected to the cooperating female connector 64 on the end of the wand 34 or alternatively, directly to the female connector 64 on the operator handle 30 at the end of the flexible hose 28. When the operator wants to connect a tool 200 directly to the handle 30, the wand 34 is removed from the handle 30. As the prongs 68, 70 of the male connector 62 are removed from the contacts 80, 82 of the cooperating female connector 64, the spring 86 biases the resilient shield 84 back into the first position illustrated in FIG. 4a where the ends 102, 104 of the resilient shield 84 prevent dirt intrusion. When the tool 200 is then connected to the handle 30, the distal end of the prongs 68, 70 engage the cam faces 88, 90 of the resilient shield 84 which is then moved out of the way in the manner described above until it reaches the second position uncovering the contacts 80, 82 for complete interconnection with the prong 68, 70 (see FIG. 4b). In this way it is possible to disconnect and reconnect the various components of the vacuum cleaner 10 in the manner described while at the same time always preventing intrusion of dust and dirt into the electrical contacts 80, 82 of the female connector 64.

In summary, numerous benefits result from employing the concepts of the present invention. Specifically, an electrical connector assembly 60 is provided for a floor care apparatus 10 or other device. That electrical connector assembly 60 includes a female connector 64 with a resilient shield 84 that effectively prevents intrusion of dirt and debris into the electrical contacts 80, 82 of the female connector 64 when that female connector is disconnected from a cooperating male connector 62. Thus, dirt and debris does not enter those contacts to degrade or interrupt electrical connection when that female connector 64 is properly connected to a cooperating male connector 62. Accordingly, the present invention represents a significant advance in the art.

The foregoing description of the preferred embodiments of the present invention have been presented for purposes of illustration and description. It is not intended to be exhaustive or to limit the invention to the precise form disclosed. Obvious modifications or variations are possible in light of the above teachings. For example, while the illustrated floor care apparatus 10 of the present invention incorporates a disposable filter/cleaning bag 22, it should be appreciated that alternatively, it could include a dirt cup. That dirt cup may include a simple filter over an outlet. Alternatively, the dirt cup may include tangential sidewalls allowing for cyclonic cleaning function in a manner known in the art. Accordingly, the terminology “dirt collection vessel” should be broadly interpreted to cover any form of disposable cleaning bag or dirt cup.

The embodiments were chosen and described to provide the best illustration of the principles of the invention and its practical application to thereby enable one of ordinary skill in the art to utilize the invention in various embodiments and with various modifications as are suited to the particular use contemplated. All such modifications and variations are within the scope of the invention as determined by the appended claims when interpreted in accordance with the breadth to which they are fairly, legally and equitably entitled. The drawings and preferred embodiments do not and are not intended to limit the ordinary meaning of the claims in their fair and broad interpretation in any way.

What is claimed:

1. An electrical connector assembly, comprising:
(a) a male connector including;
(i) a first plug body; and
(ii) a first electrical prong, said first electrical prong having a proximal end and a distal end, said proximal end being held in said first plug body; and
(b) a cooperating female connector including;
(i) a second plug body having a cavity;
(ii) a first electrical contact held in said cavity; and
(iii) a resilient shield in said cavity, said resilient shield being displaceable from a first position covering said first electrical contact to a second position exposing said first electrical contact for connection with said first electrical prong.

2. The assembly of claim 1, further including a spring in said cavity, said spring biasing said resilient shield into said first position.

3. The assembly of claim 2, wherein said male connector includes a second electrical prong having a second proximal end and a second distal end, said second proximal end being held in said plug body and said female connector includes a second electrical contact held in said cavity; in said first position said resilient shield covers said first and second electrical contacts while in said second position said resilient shield exposes said first and second electrical contacts for connection to said first and second electrical prongs.

4. The assembly of claim 3, wherein said resilient shield includes a first cam face at a first end, a second cam face at a second end and a substantially v-shaped body section connected to said first and second cam faces.

5. The assembly of claim 4, wherein said body section includes a first bend and said second plug body includes a boss, said first bend of said body section being received around said boss.

6. The assembly of claim 5, wherein said spring is substantially v-shaped and includes a second bend, said spring being received against said body section in a groove on said body section with said second bend received around said boss.

7. The assembly of claim 1, wherein said resilient shield includes a first cam face at a first end, a second cam face at a second end and a substantially v-shaped body section connected to said first and second cam faces.

8. The assembly of claim 7, wherein said body section includes a first bend and said second plug body includes a boss, said first bend of said body section being received around said boss.

9. A floor cleaning apparatus comprising:
a housing including a nozzle assembly and a canister assembly;
a suction generator carried on said housing;
a dirt collection vessel carried on said housing; and
a wand assembly including a flexible hose, an operator handle and a wand, said wand assembly further including an electrical connector assembly characterized by;
(a) a male connector including;
(i) a first plug body; and
(ii) a first electrical prong, said first electrical prong having a proximal end and a distal end, said proximal end being held in said first plug body; and
(b) a cooperating female connector including;
(i) a second plug body having a cavity;
(ii) a first electrical contact held in said cavity; and
(iii) a resilient shield received in said cavity, said resilient shield being displaceable from a first position covering said first electrical contact to a second position exposing said first electrical contact for connection with said first electrical prong.

10. The apparatus of claim 9, further including a spring received in said cavity, said spring biasing said resilient shield into said first position.

11. The assembly of claim 10, wherein said male connector includes a second electrical prong having a second proximal end and a second distal end, said second proximal end being held in said plug body and said female connector includes a second electrical contact held in said cavity; in said first position said resilient shield covers said first and second electrical contacts while in said second position said resilient shield exposes said first and second electrical contacts for connection to said first and second electrical prongs.

12. The apparatus of claim 11, wherein said resilient shield includes a first cam face at a first end, a second cam face at a second end and a substantially v-shaped body section connected to said first and second cam faces.

13. The apparatus of claim 12, wherein said body section includes a first bend and said second plug body includes a boss, said first bend of said body section being received around said boss.

14. The apparatus of claim 13, wherein said spring is substantially v-shaped and includes a second bend, said spring being received against said body section in a groove on said body section with said second bend received around said boss.

15. The apparatus of claim 9, wherein said resilient shield includes a first cam face at a first end, a second cam face at a second end and a substantially v-shaped body section connected to said first and second cam faces.

16. The apparatus of claim 15, wherein said body section includes a first bend and said second plug body includes a boss, said first bend of said body section being received around said boss.

17. A method of resisting dirt intrusion into a female electrical connector, comprising:
providing a first electrical contact of said female electrical connector in a cavity of a plug body;
providing a resilient shield in said cavity, said resilient shield being displaceable from a first position covering said first electrical contact to a second position exposing said first electrical contact for connection with a first electrical prong of a male connector.

18. The method of claim 17, including engaging said resilient shield with said first electrical prong of said male connector in order to displace said resilient shield into said second position, expose said first electrical contact and connect said first electrical prong with said first electrical contact.

19. The method of claim 18, including disconnecting said male and female connectors by removing said first electrical prong from said first electrical contact and biasing said resilient shield back into said first position covering said first electrical contact.

20. The method of claim 19, including providing a second electrical contact in said cavity of said plug body and exposing said second electrical contact for connection with a second electrical prong of a male connector.
